(19) United States
(12) Patent Application Publication
(10) Pub. No.: US 2021/0343213 A1
(43) Pub. Date: Nov. 4, 2021

(54) DISPLAY PANEL, MANUFACTURING METHOD THEREOF, AND ELECTRONIC DEVICE

(71) Applicant: SHENZHEN CHINA STAR OPTOELECTRONICS SEMICONDUCTOR DISPLAY TECHNOLOGY CO., LTD, Shenzhen, Guangdong (CN)

(72) Inventors: Xin ZHANG, Shenzhen, Guangdong (CN); Juncheng XIAO, Shenzhen, Guangdong (CN); Hongyuan XU, Shenzhen, Guangdong (CN); Jiayang FEI, Shenzhen, Guangdong (CN); Xu WANG, Shenzhen, Guangdong (CN)

(73) Assignee: SHENZHEN CHINA STAR OPTOELECTRONICS SEMICONDUCTOR DISPLAY TECHNOLOGY CO., LTD., Shenzhen, Guangdong (CN)

(21) Appl. No.: 16/970,364

(22) PCT Filed: May 19, 2020
(86) PCT No.: PCT/CN2020/091088

§ 371 Date: Aug. 16, 2020

(30) Foreign Application Priority Data
Apr. 30, 2020 (CN) 202010364279.7

(51) Int. Cl. G09G 3/20; H01L 27/12

(52) U.S. Cl. CPC G09G 3/20; H01L 27/124; G09G 2330/02; G09G 2310/0267; G09G 2310/0275; H01L 27/1259

(57) ABSTRACT

A display panel, a manufacturing method thereof, and an electronic device are provided. The display panel includes that each column of light-emitting units in a plurality of areas to be driven corresponds to data lines, first power supply lines, and second power supply lines. Driver chips are connected to scanning lines, the data lines, and the second power supply lines corresponding to the corresponding areas to be driven, and are connected to second ends of light-emitting devices in the corresponding areas to be driven, and first ends of the light-emitting devices are connected to the corresponding first power supply lines.

### FIELD OF INVENTION

The present disclosure relates to the field of display technologies, and more particularly, to a display panel, a manufacturing method thereof, and an electronic device.

### BACKGROUND OF INVENTION

Current organic light-emitting diode display panels include a plurality of light-emitting units, a plurality of scanning lines, and a plurality of data lines. In addition, the display panels further include first power supply lines and second power supply lines.

Taking a single light-emitting unit for example, as shown in FIG. 1, each light-emitting unit includes a first transistor T1 and a second transistor M1. Wherein, a gate electrode of the first transistor T1 is connected to a scanning line 11, a source electrode is connected to a data line 12, a gate electrode of the second transistor M1 is connected to a drain electrode of the first transistor T1, a source electrode of the second transistor M1 is connected to a second power supply line 14, a drain electrode of the second transistor M1 is connected to a second end of a light-emitting device D1, and a first end of the light-emitting device D1 is connected to a first power supply line 13. However, current light-emitting unit have a larger area, which causes the display panel to have a lower resolution.

### SUMMARY OF INVENTION

An objective of the present disclosure is to provide a display panel, a manufacturing method thereof, and an electronic device to improve resolution of the display panel.

To solve the above problem, an embodiment of the present disclosure provides a display panel. The display panel comprises:

a plurality of data lines, a plurality of scanning lines, a plurality of areas to be driven, and a plurality of driver chips, wherein the areas to be driven comprise a plurality of light-emitting units arranged in an array, and the light-emitting units comprise light-emitting devices;

each row of the light-emitting units in the areas to be driven corresponds to one of the scanning lines, and each column of the light-emitting units in the areas to be driven corresponds to one of the data lines, one of first power supply lines, and one of second power supply lines; and

the driver chips correspond to the areas to be driven, the driver chips are connected to the scanning lines, the data lines, and the second power supply lines corresponding to the corresponding areas to be driven, and are connected to second ends of the light-emitting devices in the corresponding areas to be driven, and first ends of the light-emitting devices are connected to the corresponding first power supply lines.

An embodiment of the present disclosure further provides an electronic device, which comprises the above display panel.

An embodiment of the present disclosure further provides a manufacturing method of a display panel, which comprises following steps:

manufacturing a first metal layer on a substrate, and patterning the first metal layer to form a first connecting part;

manufacturing a first insulating layer on the first connecting part, and manufacturing a first through-hole on the first insulating layer;

manufacturing a second metal layer in the first through-hole and on the first insulating layer, and patterning the second metal layer to form a second connecting part and a third connecting part, wherein the second connecting part is connected to the first connecting part through the first through-hole;

manufacturing a second insulating layer on the second connecting part and the third connecting part, and patterning the second insulating layer to form an opening at a position corresponding to the third connecting part and to form a second through-hole at a position corresponding to the second connecting part respectively, wherein the opening is configured to expose the third connecting part, and the second through-hole is configured to expose the second connecting part; and

bonding light-emitting devices to the third connecting part, and connecting external signals to the second connecting part.

The display panel, the manufacturing method thereof, and the electronic device of the present disclosure include: a plurality of data lines, a plurality of scanning lines, a plurality of areas to be driven, and a plurality of driver chips, wherein the areas to be driven comprise a plurality of light-emitting units arranged in an array, and the light-emitting units comprise light-emitting devices; each row of the light-emitting units in the areas to be driven corresponds to one of the scanning lines, each column of the light-emitting units in the areas to be driven corresponds to one of the data lines, one of first power supply lines, and one of second power supply lines, and the driver chips correspond to the areas to be driven; and the driver chips are connected to the scanning lines, the data lines, and the second power supply lines corresponding to the corresponding areas to be driven, and are connected to second ends of the light-emitting devices in the corresponding areas to be driven, and first ends of the light-emitting devices are connected to the corresponding first power supply lines. Since a plurality of light-emitting units share a driver chip, an area of the light-emitting units can be reduced, thereby improving resolution of the display panel.

### DESCRIPTION OF DRAWINGS

The accompanying figures to be used in the description of embodiments of the present disclosure will be described in brief to illustrate the technical solutions of the embodiments or the prior art more clearly. The accompanying figures described below are only part of the embodiments of the present disclosure, from which those skilled in the art can derive further figures without making any inventive efforts.

FIG. 1 is a schematic structural diagram of a display panel in current technology.

FIG. 2 is a schematic structural diagram of a display panel according to an embodiment of the present disclosure.

FIG. 3 is a schematic structural diagram of a display panel according to another embodiment of the present disclosure.

FIG. 4 is a schematic structural diagram of a display panel according to yet another embodiment of the present disclosure.

FIG. 5 is a schematic process diagram of a manufacturing method of a display panel according to an embodiment of the present disclosure.

FIG. 6 is a schematic structural diagram of a display panel in a sixth step of a manufacturing method of the display panel according to an embodiment of the present disclosure.

### DETAILED DESCRIPTION OF PREFERRED EMBODIMENTS

The technical solutions in the embodiments of the present disclosure will be clearly and completely described below with reference to the drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative efforts are within the scope of the present disclosure.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, “counter-clockwise”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or implicitly indicating the number of technical features indicated. Thus, features limited by “first” and “second” are intended to indicate or imply including one or more than one these features. Thus, features limited by “first” and “second” are intended to indicate or imply including one or more than one these features. In the description of the present disclosure, “a plurality of” relates to two or more than two, unless otherwise specified.

In the description of the present disclosure, it should be noted that unless there are express rules and limitations, the terms such as “mount,” “connect,” and “bond” should be comprehended in broad sense. For example, it can mean a permanent connection, a detachable connection, or an integrate connection; it can mean a mechanical connection, an electrical connection, or can communicate with each other; it can mean a direct connection, an indirect connection by an intermediate, or an inner communication or an inter-reaction between two elements. A person skilled in the art should understand the specific meanings in the present disclosure according to specific situations.

In the description of the present disclosure, unless specified or limited otherwise, it should be noted that, a structure in which a first feature is “on” or “beneath” a second feature may include an embodiment in which the first feature directly contacts the second feature and may also include an embodiment in which an additional feature is formed between the first feature and the second feature so that the first feature does not directly contact the second feature. Furthermore, a first feature “on,” “above,” or “on top of” a second feature may include an embodiment in which the first feature is right “on,” “above,” or “on top of” the second feature and may also include an embodiment in which the first feature is not right “on,” “above,” or “on top of” the second feature, or just means that the first feature has a sea level elevation greater than the sea level elevation of the second feature. While first feature “beneath,” “below,” or “on bottom of” a second feature may include an embodiment in which the first feature is right “beneath,” “below,” or “on bottom of” the second feature and may also include an embodiment in which the first feature is not right “beneath,” “below,” or “on bottom of” the second feature, or just means that the first feature has a sea level elevation less than the sea level elevation of the second feature.

The following description provides many different embodiments or examples for implementing different structures of the present disclosure. In order to simplify the present disclosure, the components and settings of a specific example are described below. Of course, they are merely examples and are not intended to limit the present disclosure. In addition, the present disclosure may repeat reference numerals and/or reference letters in different examples, which are for the purpose of simplicity and clarity, and do not indicate the relationship between the various embodiments and/or arrangements discussed. In addition, the present disclosure provides examples of various specific processes and materials, but one of ordinary skill in the art will recognize the use of other processes and/or the use of other materials.

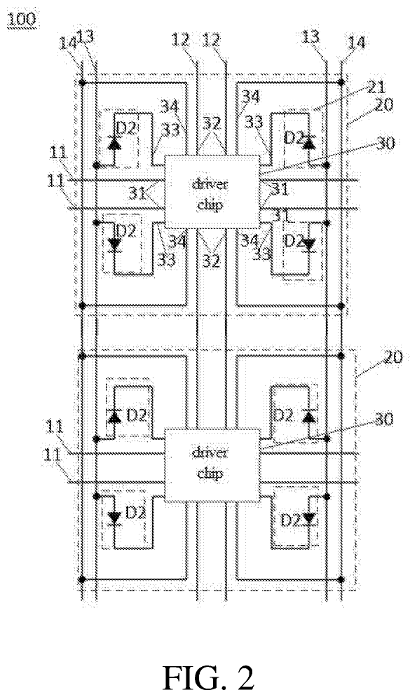

Referring to FIG. 2, FIG. 2 is a schematic structural diagram of a display panel according to an embodiment of the present disclosure.

As shown in FIG. 2, a display panel 100 in the embodiment includes a plurality of scanning lines 11, a plurality of data lines 12, a plurality of areas to be driven 20, and a plurality of driver chips 30, wherein the areas to be driven 20 comprise a plurality of light-emitting units 21 arranged in an array, and the light-emitting units 21 comprise light-emitting devices D2.

Each row of the light-emitting units 21 in the areas to be driven 20 corresponds to one of the scanning lines 11, and each column of the light-emitting units 21 in the areas to be driven 20 corresponds to one of the data lines 12, one of first power supply lines 13, and one of second power supply lines 14. In an embodiment of the present disclosure, each row of the light-emitting units 21 in the areas to be driven 20 corresponds to the scanning lines by one-to-one, and each column of the light-emitting units 21 in the areas to be driven 20 corresponds to the data lines 12, the first power supply lines 13, and the second power supply lines 14 all by one-to-one. Of course, the above correspondence is not limited to this.

The driver chips 30 correspond to the areas to be driven 20. The driver chips 30 are respectively connected to the scanning lines 11, the data lines 12, and the second power supply lines 14 which correspond to the light-emitting units 21 in the corresponding areas to be driven 20, and in addition, the driver chips 30 are further connected to second ends of the light-emitting devices D2 in the corresponding areas to be driven 20. The driver chips 30 are used to drive every light-emitting unit 21 in the areas to be driven 20. For example, in an embodiment of the present disclosure, first ends of the light-emitting devices D2 are anodes, and the second ends of the light-emitting devices D2 are cathodes. In an embodiment of the present disclosure, in order to improve uniformity of brightness and display effect, the areas to be driven 20 correspond to the driver chips 30 by one-to-one.

FIG. 2 takes the areas to be driven 20 as an example, where each area to be driven 20 includes two rows and two columns of the light-emitting units 21, each row of the light-emitting units 21 corresponds to one scanning line 11, and each column of the light-emitting units 21 respectively corresponds to one data line 12, one first power supply line 13, and one second power supply line 14, which cannot constitute a limitation to the present disclosure.

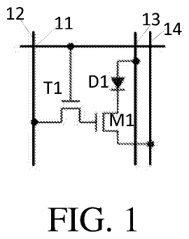

In order to improve driving efficiency, in an embodiment of the present disclosure, each of the driver chips 30 includes four scanning signal input terminals 31, four data signal input terminals 32, four power supply control terminals 33, and four power supply access terminals 34. The scanning signal input terminals 31 are connected to the scanning lines 11 corresponding to the corresponding areas to be driven 20 (the scanning lines 11 corresponding to each of the light-emitting devices D2 in the areas to be driven 20), the data signal input terminals 32 are connected to the corresponding data lines 12 of the corresponding areas to be driven 20, the power supply control terminals 33 are connected to the second ends of each light-emitting device D2 in the corresponding areas to be driven 20, the first ends of the light-emitting devices D2 are connected to the corresponding first power supply lines 13, and the power supply access terminals 34 are connected to the second power supply lines 14 corresponding to the corresponding areas to be driven 20. Wherein, voltages connected to the first power supply lines 13 are, for example, VDD, voltages connected to the second power supply lines 14 are, for example, VSS, and VDD is greater than VSS. It can be understood that the driver chips 30 can also include two scanning signal input terminals 31 and two data signal input terminals 32. That is, the scanning signal input terminals correspond to the scanning lines connected to the areas to be driven 20, and the data signal input terminals correspond to the data lines connected to the areas to be driven 20. Of course, it can be understood that numbers of the scanning signal input terminals 31, the data signal input terminals 32, the power supply control terminals 33, and the power supply access terminals 34 are not limited to this, and the specific numbers can be set according to actual needs. In an embodiment of the present disclosure, each of the driver chips 30 is an integrated chip having four driving modules, each driving module includes a first transistor and a second transistor, and a specific connecting method of the first transistor and the second transistor can be referred to FIG. 1. Of course, a specific structure of the driver chips 30 is not limited to this.

In an embodiment of the present disclosure, in order to further reduce an area of the light-emitting units to thereby further improve resolution, the areas to be driven 20 include gap areas (not shown in the figure), the gap areas consist of gaps between two adjacent light-emitting units 21, and the driver chips 30 are disposed in the gap areas. That is, the driver chips 30 correspond to positions of the gap areas. In an embodiment of the present disclosure, in order to further reduce lengths of connecting lines connecting the driver chips to the corresponding light-emitting units, each of the areas to be driven 20 has a geometric center, for example, the areas to be driven 20 are rectangular, and geometric centers of the areas to be driven 20 overlap geometric centers of the rectangles. Positions of the driver chips 30 correspond to positions of the geometric centers of the corresponding areas to be driven 20, thereby reducing voltage drops and improving the uniformity of brightness. Of course, the positions of the driver chips 30 are not limited to this.

In an embodiment of the present disclosure, in order to further reduce lengths of connecting lines connecting the driver chips 30 to the data lines 12 or the scanning lines 11, an orthographic projection of all the data lines 12 corresponding to the areas to be driven 20 on a predetermined plane partially overlaps an orthographic projection of the driver chips 30 on the predetermined plane, wherein, the predetermined plane is a plane where the display panel 100 is located; and/or an orthographic projection of all the scanning lines 11 corresponding to the areas to be driven 20 on the predetermined plane partially overlaps the orthographic projection of the driver chips 30 on the predetermined plane. In an embodiment of the present disclosure, the plurality of data lines 12 corresponding to the areas to be driven 20 are disposed adjacently and are disposed between two adjacent columns of light-emitting units 21. The plurality of scanning lines 11 corresponding to the areas to be driven 20 are disposed adjacently and are disposed between two adjacent rows of light-emitting units 21.

In an embodiment of the present disclosure, in order to reduce lengths of connecting lines connecting the first ends of the light-emitting devices D2 to the first power supply lines 13, two adjacent first power supply lines 13 corresponding to the areas to be driven 20 are symmetrically disposed with respect to the areas to be driven 20. In an embodiment of the present disclosure, two adjacent second power supply lines 14 may be symmetrically disposed with respect to the areas to be driven 20 or may be disposed between two adjacent columns of light-emitting units 21.

Although FIG. 2 only demonstrates two areas to be driven 20 and two driver chips 30, this cannot constitute a limitation to the present disclosure, and numbers of the areas to be driven and driver chips of the present disclosure may be greater than or equal to two.

FIG. 2 shows that each of the areas to be driven 20 includes two rows and two columns of light-emitting devices 21, but this cannot constitute a limitation to the present disclosure.

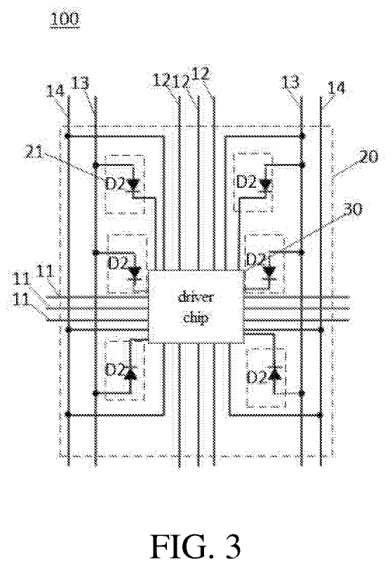

For example, in an another embodiment, as shown in FIG. 3, an area to be driven 20 includes three rows and two columns of light-emitting units 21, and in an embodiment, each of the areas to be driven 20 includes m rows and n columns of light-emitting devices, wherein, m is greater than or equal to n, and n is equal to 2, thereby reducing the lengths of the connecting lines connecting the data lines to the driver chips. In another embodiment of the present disclosure, each of the areas to be driven 20 includes two rows and three columns of light-emitting units, and in another embodiment, each of the areas to be driven 20 includes four rows and four columns of light-emitting units, etc., that is, each of the driver chips 30 can drive two rows and two columns of light-emitting units or more light-emitting units. When each of the areas to be driven 20 includes two rows and two columns of light-emitting units 21, it is convenient to reduce the lengths of the connecting lines connected to the driver chips 30, thereby reducing the voltage drops and improving the uniformity of brightness.

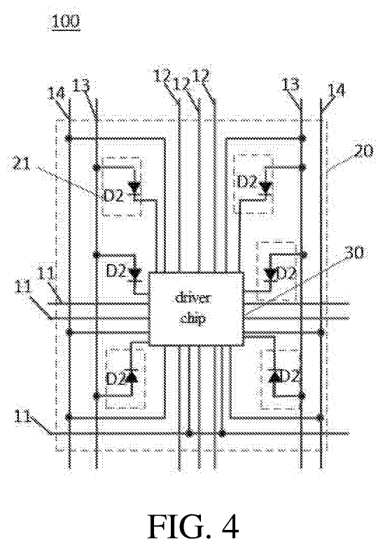

As shown in FIG. 4, an orthographic projection of a part of scanning lines 11 corresponding to an area to be driven 20 on a predetermined plane partially overlaps an orthographic projection of a driver chip 30 on the predetermined plane. For example, the orthographic projection of the above two scanning lines 11 on the predetermined plane partially overlaps the orthographic projection of the driver chip 30 on the predetermined plane. Of course, it can be understood that in other embodiment, an orthographic projection of a part of data lines 12 corresponding to the area to be driven 20 on the predetermined plane partially overlaps the orthographic projection of the driver chip 30 on the predetermined plane. The above two embodiments may exist at a same time.

An embodiment of the present disclosure further provides an electronic device, which includes any one of the above display panels. The electronic device includes but is not limited to mobile phones, tablet computers, computer monitors, game consoles, televisions, display screens, wearable devices, other household appliances with display functions, etc.

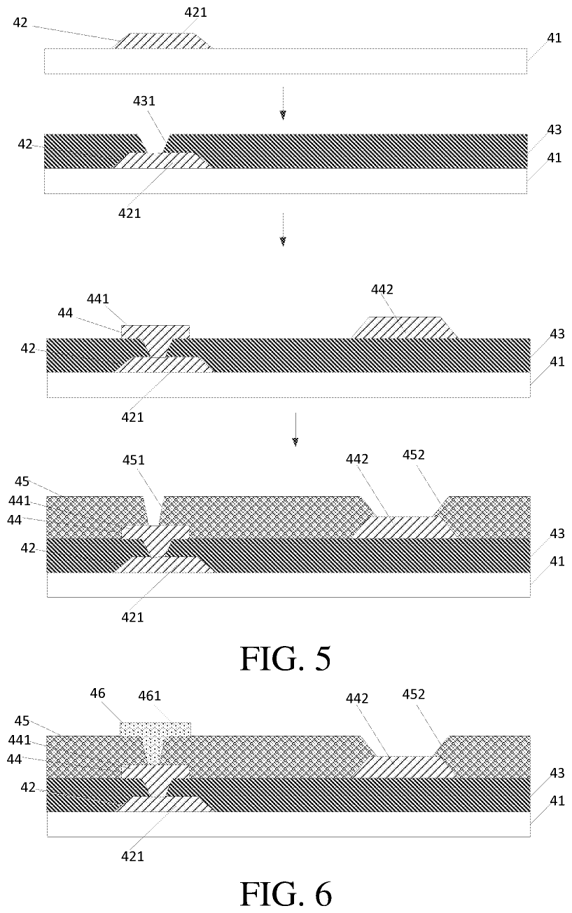

An embodiment of the present disclosure further provides a manufacturing method of a display panel, as shown in FIG. 5, which comprises following steps:

S101: manufacturing a first metal layer 42 on a substrate 41, and patterning the first metal layer 42 to form a first connecting part 421.

For example, the substrate 41 may be a glass substrate, and a material for the first metal layer 42 may include at least one of transparent conductive material, Mo, Cu, Al, or Ti.

S102: manufacturing a first insulating layer 43 on the first connecting part 421, and manufacturing a first through-hole 431 on the first insulating layer 43.

For example, a material for the first insulating layer 43 may include but is not limited to aluminum oxide, silicon nitride, silicon dioxide, and aluminum nitride.

S103: manufacturing a second metal layer 44 in the first through-hole 431 and on the first insulating layer 43, and patterning the second metal layer 44 to form a second connecting part 441 and a third connecting part 442.

Wherein, the second connecting part 441 is connected to the first connecting part 421 through the first through-hole 431 to constitute a signal line, and the signal line may be used as a first power supply line or a second power supply line. For example, a material for the second metal layer 45 includes at least one of transparent conductive material, Mo, Cu, Al, or Ti. A metal material which is not easy to oxidize is preferred, such as Ti.

S104: manufacturing a second insulating layer 45 on the second connecting part 441 and the third connecting part 442, and patterning the second insulating layer 45 to form a second through-hole 451 at a position corresponding to the second connecting part 441 and to form an opening 452 at a position corresponding to the third connecting part 442 respectively.

Wherein, the opening 452 is used to expose the third connecting part 442, and the second through-hole 451 is used to expose the second connecting part 441.

A material for the second insulating layer 45 may include but is not limited to aluminum oxide, silicon nitride, silicon dioxide, and aluminum nitride.

S105: bonding light-emitting devices to the third connecting part 442, and connecting external signals to the second connecting part.

Wherein, the light-emitting devices may include organic light-emitting diodes or miniature light-emitting diodes, and when the light-emitting devices are miniature light-emitting diodes, the display effect can be further improved. The second connecting part 441 can receive the external signals, and the external signals are, for example, power supply voltages VSS or VDD.

As shown in FIG. 6, the method can also include:

S106: manufacturing a transparent conductive layer 46 in the second through-hole 451 and on the second insulating layer 45, and patterning the transparent conductive layer 46 to form a connecting terminal 461.

Wherein, the external signals are passed to the second connecting part 441 through the connecting terminal 461.

The connecting terminal 461 is used to receive the external signals, such as power supply voltages VSS or VDD. When the second metal layer 44 is a metal material which is easily oxidized, such as copper, manufacturing the connecting terminal 461 on the second metal layer 44 can prevent the second connecting part 441 from being oxidized, thereby improving stability of signal transmission.

In an embodiment of the present disclosure, the driver chips 30 are bonded to the display panel 100 by patches, and a specific setting method of the driver chips 30 is not limited to this.

Since a plurality of light-emitting units share a driver chip, an area of the light-emitting units can be reduced, thereby improving resolution of the display panel. In addition, since it is not necessary to dispose a single driving circuit for each light-emitting unit, a number of packaging is reduced, thereby improving production efficiency and reducing production cost.

The display panel, the manufacturing method thereof, and the electronic device of the present disclosure include: a plurality of data lines, a plurality of scanning lines, a plurality of areas to be driven, and a plurality of driver chips, wherein the areas to be driven comprise a plurality of light-emitting units arranged in an array, and the light-emitting units comprise light-emitting devices; each row of the light-emitting units in the areas to be driven corresponds to one of the scanning lines, each column of the light-emitting units in the areas to be driven corresponds to one of the data lines, one of first power supply lines, and one of second power supply lines, and the driver chips correspond to the areas to be driven; and the driver chips are connected to the scanning lines, the data lines, and the second power supply lines corresponding to the corresponding areas to be driven, and are connected to second ends of the light-emitting devices in the corresponding areas to be driven, and first ends of the light-emitting devices are connected to the corresponding first power supply lines. Since a plurality of light-emitting units share a driver chip, an area of the light-emitting units can be reduced, thereby improving resolution of the display panel.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A display panel, comprising:
a plurality of data lines, a plurality of scanning lines, a plurality of areas to be driven, and a plurality of driver chips, wherein the areas to be driven comprise a plurality of light-emitting units arranged in an array, and the light-emitting units comprise light-emitting devices;
each row of the light-emitting units in the areas to be driven corresponds to one of the scanning lines, and each column of the light-emitting units in the areas to be driven corresponds to one of the data lines, one of first power supply lines, and one of second power supply lines; and
the driver chips correspond to the areas to be driven, the driver chips are connected to the scanning lines, the data lines, and the second power supply lines corresponding to the corresponding areas to be driven, and are connected to second ends of the light-emitting devices in the corresponding areas to be driven, and first ends of the light-emitting devices are connected to the corresponding first power supply lines.

2. The display panel according to claim 1, wherein the driver chips comprise:
a plurality of scanning signal input terminals connected to the scanning lines corresponding to the corresponding areas to be driven;
a plurality of data signal input terminals connected to the data lines corresponding to the corresponding areas to be driven;
a plurality of power supply access terminals connected to the second power supply lines corresponding to the corresponding areas to be driven; and
a plurality of power supply control terminals connected to the second ends of the light-emitting devices in the corresponding areas to be driven.

3. The display panel according to claim 1, wherein the areas to be driven comprise gap areas, and the driver chips are disposed in the gap areas.

4. The display panel according to claim 3, wherein positions of the driver chips correspond to positions of geometric centers of the corresponding areas to be driven.

5. The display panel according to claim 4, wherein an orthographic projection of at least a part of the data lines corresponding to the areas to be driven on a predetermined plane partially overlaps an orthographic projection of the driver chips on the predetermined plane; and/or
an orthographic projection of at least a part of the scanning lines corresponding to the areas to be driven on the predetermined plane partially overlaps the orthographic projection of the driver chips on the predetermined plane.

6. The display panel according to claim 5, wherein an orthographic projection of all the data lines corresponding to the areas to be driven on the predetermined plane partially overlaps the orthographic projection of the driver chips on the predetermined plane; and/or
an orthographic projection of all the scanning lines corresponding to the areas to be driven on the predetermined plane partially overlaps the orthographic projection of the driver chips on the predetermined plane.

7. The display panel according to claim 1, wherein two adjacent first power supply lines corresponding to the areas to be driven are symmetrically disposed with respect to the areas to be driven.

8. The display panel according to claim 1, wherein each of the areas to be driven comprises two rows and two columns of the light-emitting units.

9. The display panel according to claim 1, wherein the areas to be driven correspond to the driver chips by one-to-one.

10. An electronic device, comprising a display panel comprising:
a plurality of data lines, a plurality of scanning lines, a plurality of areas to be driven, and a plurality of driver chips, wherein the areas to be driven comprise a plurality of light-emitting units arranged in an array, and the light-emitting units comprise light-emitting devices;
each row of the light-emitting units in the areas to be driven corresponds to one of the scanning lines, and each column of the light-emitting units in the areas to be driven corresponds to one of the data lines, one of first power supply lines, and one of second power supply lines; and
the driver chips correspond to the areas to be driven, the driver chips are connected to the scanning lines, the data lines, and the second power supply lines corresponding to the corresponding areas to be driven, and are connected to second ends of the light-emitting devices in the corresponding areas to be driven, and first ends of the light-emitting devices are connected to the corresponding first power supply lines.

11. The electronic device according to claim 10, wherein the driver chips comprise:
a plurality of scanning signal input terminals connected to the scanning lines corresponding to the corresponding areas to be driven;
a plurality of data signal input terminals connected to the data lines corresponding to the corresponding areas to be driven;
a plurality of power supply access terminals connected to the second power supply lines corresponding to the corresponding areas to be driven; and
a plurality of power supply control terminals connected to the second ends of the light-emitting devices in the corresponding areas to be driven.

12. The electronic device according to claim 10, wherein the areas to be driven comprise gap areas, and the driver chips are disposed in the gap areas.

13. The electronic device according to claim 12, wherein positions of the driver chips correspond to positions of geometric centers of the corresponding areas to be driven.

14. The electronic device according to claim 13, wherein an orthographic projection of at least a part of the data lines corresponding to the areas to be driven on a predetermined plane partially overlaps an orthographic projection of the driver chips on the predetermined plane; and/or
an orthographic projection of at least a part of the scanning lines corresponding to the areas to be driven on the predetermined plane partially overlaps the orthographic projection of the driver chips on the predetermined plane.

15. The electronic device according to claim 14, wherein an orthographic projection of all the data lines corresponding to the areas to be driven on the predetermined plane partially overlaps the orthographic projection of the driver chips on the predetermined plane; and/or
an orthographic projection of all the scanning lines corresponding to the areas to be driven on the predetermined plane partially overlaps the orthographic projection of the driver chips on the predetermined plane.

16. The electronic device according to claim 10, wherein two adjacent first power supply lines corresponding to the areas to be driven are symmetrically disposed with respect to the areas to be driven.

17. The electronic device according to claim 10, wherein each of the areas to be driven comprises two rows and two columns of the light-emitting units.

18. The electronic device according to claim 10, wherein the areas to be driven correspond to the driver chips by one-to-one.

19. A manufacturing method of a display panel, comprising following steps:
manufacturing a first metal layer on a substrate, and patterning the first metal layer to form a first connecting part;
manufacturing a first insulating layer on the first connecting part, and manufacturing a first through-hole on the first insulating layer;
manufacturing a second metal layer in the first through-hole and on the first insulating layer, and patterning the second metal layer to form a second connecting part and a third connecting part, wherein the second connecting part is connected to the first connecting part through the first through-hole;
manufacturing a second insulating layer on the second connecting part and the third connecting part, and patterning the second insulating layer to form an opening at a position corresponding to the third connecting part and to form a second through-hole at a position corresponding to the second connecting part respectively, wherein the opening is configured to expose the third connecting part, and the second through-hole is configured to expose the second connecting part; and
bonding light-emitting devices to the third connecting part, and connecting external signals to the second connecting part.

20. The manufacturing method of the display panel according to claim 19, further comprising:
manufacturing a transparent conductive layer in the second through-hole and on the second insulating layer, and patterning the transparent conductive layer to form a connecting terminal, wherein the external signals are passed to the second connecting part through the connecting terminal.
